(19) United States
(12) Patent Application Publication
(10) Pub. No.: US 2023/0112388 A1
(43) Pub. Date: Apr. 13, 2023

(54) DISPLAY DEVICE

(71) Applicant: SAMSUNG DISPLAY CO., LTD., Yongin-si (KR)

(72) Inventors: Joohyeon Lee, Yongin-si (KR); Hyunjoon Oh, Yongin-si (KR); Taehyeog Jung, Yongin-si (KR)

(21) Appl. No.: 17/950,338

(22) Filed: Sep. 22, 2022

(30) Foreign Application Priority Data
Sep. 24, 2021 (KR) 10-2021-0126542

(51) Int. Cl. G06F 1/16

(52) U.S. Cl. CPC G06F 1/1656; G06F 1/1616; G06F 1/1652

(57) ABSTRACT

A display device includes a display panel in which a display element is disposed, a first film on the display panel, a second film on the first film, and a first adhesive layer between the first film and the display panel, wherein the first film includes a first layer adjacent to the second film, and a second layer between the first layer and the first adhesive layer, where an elastic modulus of the second layer is different from an elastic modulus of the first layer.

This application claims priority to Korean Patent Application No. 10-2021-0126542, filed on Sep. 24, 2021, and all the benefits accruing therefrom under 35 U.S.C. §119, the content of which in its entirety is herein incorporated by reference.

### BACKGROUND

### 1. Field

One or more embodiments relate to a display, and more particularly, to a display device.

### 2. Description of the Related Art

Recently, display devices that can be bent or folded, that is, bendable or foldable display devices, have been actively developed. Such a display device may include various members such as a flexible display panel and a flexible window. The various members may be bent or folded together with a display panel by being attached to an upper or lower portion of the display panel.

### SUMMARY

In a bendable or foldable display device, although various bendable or foldable members are included, reliability against an external impact may be reduced if the various members have flexible properties.

One or more embodiments include a display device capable of preventing or minimizing damage to a display panel due to an external impact.

According to one or more embodiments, a display device includes a display panel on which a display element is disposed, a first film on the display panel, a second film on the first film, and a first adhesive layer between the first film and the display panel, where the first film includes a first layer adjacent to the second film, and a second layer between the first layer and the first adhesive layer, where an elastic modulus of the second layer is different from an elastic modulus of the first layer.

In an embodiment, the elastic modulus of the first layer may be greater than the elastic modulus of the second layer.

In an embodiment, the elastic modulus of the first layer may be about 600 megapascals (MPa) or greater and about 1.5 GPa or less.

In an embodiment, an elastic modulus of the first film may be about 700 MPa or greater and about 1.2 GPa or less.

In an embodiment, the elastic modulus of the second layer may be about 5 MPa or greater and about 30 MPa or less.

In an embodiment, the second layer may include an acryl-based and/or a silicone-based resin.

In an embodiment, the display device may further include a second adhesive layer between the first layer and the second film.

In an embodiment, the display device may further include a third film on the second film.

In an embodiment, the display device may further include a third adhesive layer between the third film and the second film.

In an embodiment, a yield strain of the first film may be about 2.9% or less.

According to one or more embodiments, a display device includes a display panel, a first film on the display panel, a second film on the first film, and a first adhesive layer between the first film and the display panel, where the first film includes a first portion and a second portion having different elastic moduli from each other.

In an embodiment, the elastic modulus of the second portion may be less than the elastic modulus of the first layer.

In an embodiment, the elastic modulus of the first portion may be about 600 MPa or greater and about 1.5 GPa or less.

In an embodiment, the elastic modulus of the second portion may be about 5 MPa or greater and about 30 MPa or less.

In an embodiment, the second portion may include an acryl-based and/or a silicone-based resin.

In an embodiment, an elastic modulus of the first film may be about 700 MPa or greater and about 1.2 GPa or less.

In an embodiment, the display device may further include a second adhesive layer between the second film and the first film.

In an embodiment, the display device may further include a third film on the second film.

In an embodiment, the display device may further include a third adhesive layer between the third film and the second film.

In an embodiment, a yield strain of the first film may be about 2.9% or less.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view of a display device according to an embodiment;

FIG. 2 is a perspective view of a display device according to an embodiment;

FIG. 3 is a cross-sectional view of the display device shown in FIG. 1;

FIG. 4 is a plan view of a display panel shown in FIG. 1;

FIGS. 5 and 6 are equivalent circuit diagrams of a pixel circuit for driving a pixel according to an embodiment;

FIG. 7 is a cross-sectional view of a cross-section of a display device according to an embodiment; and

FIGS. 8A and 8B are plan views of experimental examples of a conventional display device and a display device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

Since the disclosure may have diverse modified embodiments, certain embodiments are illustrated in the drawings and are described in the detailed description. Advantages and features of the disclosure, and implementation methods thereof will be clarified through following embodiments described with reference to the accompanying drawings. The disclosure may, however, be embodied in many different forms and should not be construed as limited to the embodiments set forth herein.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “a first component,” “a first region,” “a first layer” or “a first section” discussed below could be termed “a second element,” “a second component,” “a second region,” “a second layer” or “a second section” without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element’s relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Sizes of elements in the drawings may be exaggerated for convenience of explanation. In other words, since sizes and thicknesses of components in the drawings are arbitrarily illustrated for convenience of explanation, the following embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ± 30%, ±20%, ±10% or ±5% of the stated value.

In the following embodiments, an x direction, a y direction, and a z direction are not limited to three axes on an orthogonal coordinate system and may be widely understood. For example, the x direction, the y direction, and the z direction may be perpendicular to one another or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

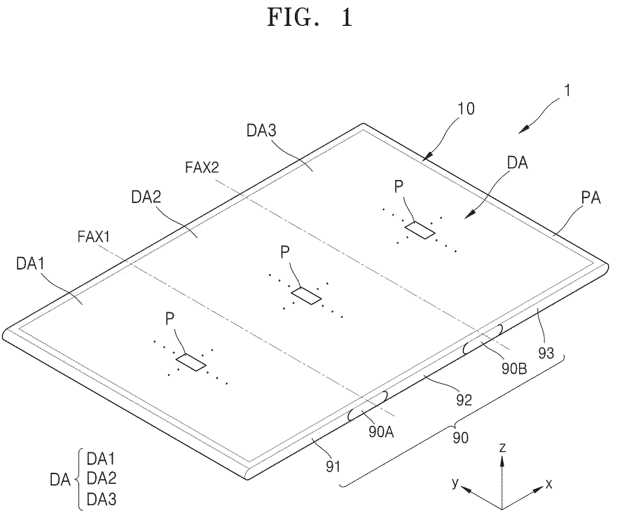

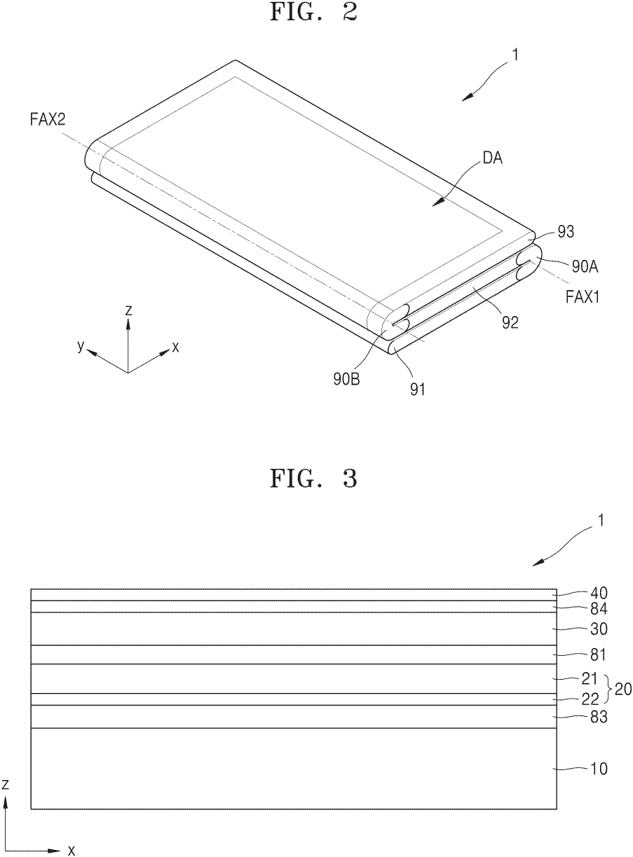

FIGS. 1 and 2 are perspective views of a display device 1 according to an embodiment. In more detail, FIG. 1 is a perspective view illustrating a display device 1 in an unfolded state, and FIG. 2 is a perspective view illustrating the display device 1 in a folded state.

Referring to FIGS. 1 and 2, an embodiment of the display device 1 may include a display panel 10 and a lower cover 90. The display panel 10 may include a display area DA in which an image is displayed, and a peripheral area PA around the display area DA. Pixels P including a display element may be arranged in the display area DA. The display device 1 may provide an image using light emitted from the pixels P arranged in the display area DA, and the peripheral area PA may be a non-display area in which a pixel P is not arranged.

The display area DA may include a first display area DA1, a second display area DA2, and a third display area DA3. The pixels P may be respectively arranged in the first display area DA1, the second display area DA2, and the third display area DA3. The display device 1 may provide an image through pixels P respectively arranged in the first display area DA1, the second display area DA2, and the third display area DA3. The first display area DA1, the second display area DA2, and the third display area DA3 may be surrounded by the peripheral area PA.

Hereinafter, for convenience of description, embodiments where the display device 1 is an organic light-emitting display device will be described in detail, but a display device of the disclosure is not limited thereto. In an alternative embodiment, the display device 1 of the disclosure may be an inorganic light-emitting (“EL”) display or a quantum dot light emitting display. In an embodiment, for example, a light-emitting layer of a display element provided in the display device 1 may include organic material, inorganic material, quantum dots, organic material and quantum dots, or inorganic material and quantum dots.

In an embodiment, the display panel 10 may be a flexible display panel that is flexible and can be easily bent, folded, or rolled. In an embodiment, for example, the display panel 10 may include a foldable display panel that can be folded and unfolded, a curved display panel with a curved display surface, a bended display panel with curved areas other than the display surface, a rollable display panel that can be rolled or unfolded, or a stretchable display panel that can be stretched. In an alternative embodiment, the display panel 10 may be a rigid display panel that is rigid and is not easily bent.

In an embodiment, the display panel 10 may include a first folding axis FAX1 and a second folding axis FAX2. The display panel 10 may be folded based on the first folding axis FAX1 and the second folding axis FAX2.

The first display area DA1 and the second display area DA2 may be defined with the first folding axis FAX1 therebetween. In addition, the second display area DA2 and the third display area DA3 may be defined with the second folding axis FAX2 therebetween.

The lower cover 90 may form the lower exterior of the display device 1. The lower cover 90 may include a plastic, a metal, or both a plastic and a metal. The lower cover 90 may include a first portion 91, a second portion 92, and a third portion 93 supporting the display panel 10. The lower cover 90 may be folded around the first folding axis FAX1 between the first portion 91 and the second portion 92. In addition, the lower cover 90 may be folded around the second folding axis FAX2 between the second portion 92 and the third portion 93.

In an embodiment, a first hinge portion 90A may be provided or disposed between the first portion 91 and the second portion 92, and a second hinge portion 90B may be provided between the second portion 92 and the third portion 93.

In an embodiment, the first display area DA1 and the second display area DA2 may be folded to face each other based on the first folding axis FAX1. In such an embodiment, the first portion 91 and the second portion 92 may be folded to face each other based on the first folding axis FAX1. In an embodiment, the first display area DA1 and the second display area DA2 may be folded not to face each other based on the first folding axis FAX1.

In an embodiment, the second display area DA2 and the third display area DA3 may be folded not to face each other based on the second folding axis FAX2. In such an embodiment, the second portion 92 and the third portion 93 may be folded to face each other based on the second folding axis FAX2. In an embodiment, the second display area DA2 and the third display area DA3 may be folded to face each other based on the second folding axis FAX2.

In an embodiment, in a case of in-folding in which the first display area DA1 and the second display area DA2 are folded to face each other, a curvature of the folded portion may be 5R or less. Here, R is a predetermined constant. Alternatively, in a case of in-folding in which the first display area DA1 and the second display area DA2 are folded to face each other, a curvature of the folded portion may be 3R or less, or 1R or less.

In an embodiment, in a case of out-folding in which the second display area DA2 and the third display area DA3 are folded not to face each other, a curvature of the folded portion may be 5R or less. Alternatively, in a case of out-folding in which the second display area DA2 and the third display area DA3 are folded not to face each other, a curvature of the folded portion may be 4R or less.

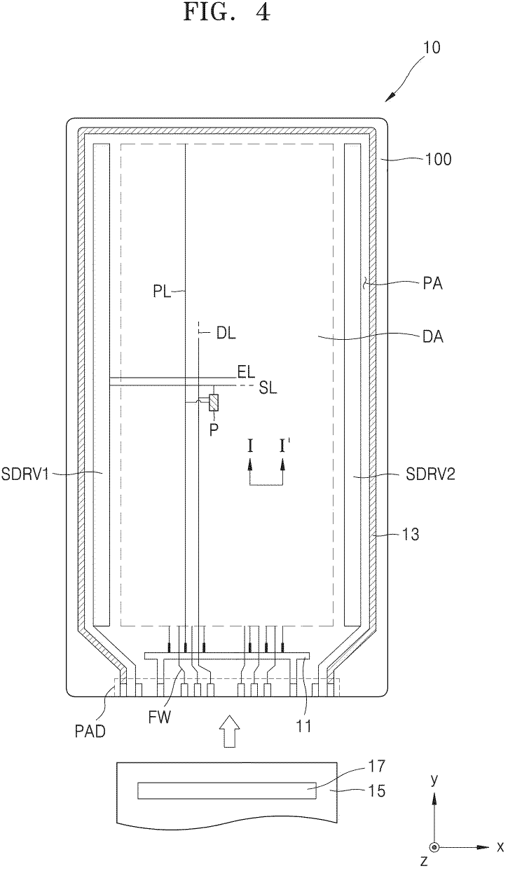

FIG. 3 is a cross-sectional view of the display device 1 shown in FIG. 1.

Referring to FIG. 3, an embodiment of the display device 1 may include the display panel 10. A first film 20 may be on the display panel 10, a second adhesive layer 81 may be on the first film 20, and a first adhesive layer 83 may be between the display panel 10 and the first film 20.

The first film 20 may be on one surface of the display panel 10. A thickness of the first film 20 may be in a range of about 50 micrometers (µm) to about 150 µm. In this case, if the thickness of the first film 20 is less than about 50 µm, the display panel 10 may be damaged by an external impact of the display device 1. On the other hand, if the thickness of the first film 20 is greater than about 150 µm, folding properties of the display device 1 may be deteriorated. Accordingly, in an embodiment, the thickness of the first film 20 is in the range of about 50 µm to about 150 µm, such that damage to the display panel 10 from an external impact may be effectively prevented or minimized, and at the same time, the display device 1 may be easily folded.

A yield strain of the first film 20 as described above may be about 2.9% or less. In this case, if the yield strain of the first film 20 exceeds 2.9%, folding of the display panel 10 may be prevented when the display device 1 is folded.

In an embodiment, the elastic modulus of the first film 20 as described above may have a value in the range of about 700 megapascals (MPa) to about 1.2 gigapascals (GPa). In this case, if the elastic modulus of the first film 20 is less than about 700 MPa, the first film 20 is easily deformed, so that the display panel 10 may not be supported. On the other hand, if the elastic modulus of the first film 20 exceeds about 1.2 GPa, excessive force may be used to deform the first film 20 when the display panel 10 is folded, so it may be difficult for a user to use the display device 1 and the first film 20 may be damaged.

In an embodiment, the first film 20 may include a first layer 21 and a second layer 22 that are integrally formed with each other as a single unitary unit. In such an embodiment, the elastic modulus of the first layer 21 may be different from the elastic modulus of the second layer 22. In an embodiment, for example, the elastic modulus of the first layer 21 may be greater than the elastic modulus of the second layer 22.

The first layer 21 may be a high elastic and high recovery film. In an embodiment, the first layer 21 may include an elastomeric material. Because the first layer 21 includes an elastomeric material, stress generated when the display device 1 is bent or folded may be reduced to improve the folding properties of the display device 1 and at the same time, repulsion and recovery properties of the display device 1 may be improved.

In an embodiment, the elastic modulus of the first layer 21 may be in a range of about 600 MPa to about 1.5 GPa. In this case, if the elastic modulus of the first layer 21 is less than about 600 MPa, the first layer 21 may not prevent sagging due to the load of a second film 30 or the load of the display panel 10. In addition, if the elastic modulus of the first layer 21 exceeds about 1.5 GPa, excessive force may be required when the display device 1 is folded or the first layer 21 may be damaged.

In an embodiment, a recovery rate of the first layer 21 may be about 80% or greater. In this case, the recovery rate of the first layer 21 is calculated using a universal testing machine (“UTM”), and the level of recovery is calculated as a residual strain after 100 cycles of a 5% tensile reciprocating test for the first layer 21.

In an embodiment, a viscoelastic strain of the first layer 21 may be about 40% or less. In this case, due to the viscoelastic strain of the first layer 21, it is possible to calculate how much the first layer 21 is stretched compared to its initial length after the first layer 21 is stretched for a certain time (e.g., about 1 hour) with a constant force. Such tests and the like may be performed at a room temperature (e.g., about 25° C.).

Because the first layer 21 has high elasticity and high resilience properties, the display device 1 may have high resilience while being flexible, and scratch resistance and impact resistance of the display device 1 may be improved.

The first layer 21 as described above may include an amide-based resin, an ester-based resin, an ether-based resin, and/or a carbonate-based resin. In such an embodiment, the first layer 21 may be formed in the form of a film.

The elastic modulus of the second layer 22 may be about 5 MPa or greater and about 30 MPa or less, that is, in a range of about 5 MPa to about 30 MPa. In this case, if the elastic modulus of the second layer 22 is less than about 5 MPa, the second layer 22 may not sufficiently absorb the impact when an impact is applied from the outside. In addition, if the elastic modulus of the second layer 22 exceeds about 30 MPa, the second layer 22 may be separated from the first layer 21 or may affect other films or the like due to excessive vibration when there is an external impact.

The second layer 22 may be formed directly or coated on one surface of the first layer 21. In an embodiment, for example, the second layer 22 may be formed by supplying a resin to one surface of the first layer 21 through a nozzle or the like, or may be arranged on one surface of the first layer 21 by a spray method. In such an embodiment, the second layer 22 may include an acryl-based resin, a urethane-based resin, and/or a silicone-based resin.

When the first film 20 as described above is tested in various combinations, results as shown in Table 1 and Table 2 below may be obtained. Table 1 shows the properties of components of the first layer 21 and the second layer 22 of the first film 20, and Table 2 shows test results of the first film 20 including the first layer 21 and the second layer 22. In addition, in Table 1, ‘Thickness’ denotes a thickness of each layer or film, ‘Modulus’ denotes the elastic modulus, and ‘εγ’ denotes a yield strain. In addition, ‘Cycle’ denotes a recovery rate, and ‘Creep’ denotes a viscoelastic strain.

In addition, in Table 1, ‘Resin’ denotes the second layer 22, and ‘Film’ denotes the first layer 21. In Table 2, ‘Film/Resin’ denotes the first film 20 manufactured by stacking the first layer 21 and the second layer 22 with respective materials.

TABLE 1

| Properties | Monolayer | | | | |
|---|---|---|---|---|---|
| | Resin A | Resin B | Resin C | Film b | Film c |
| Thickness (µm) | 100 | 100 | 100 | 40 | 40 |
| Modulus (MPa) | 13 | 11 | 31 | 1400 | 4500 |
| εγ(%) | 1.8 | 2.1 | 1.9 | 2.2 | 1.9 |
| Cycle (%) | 93 | 95 | 90 | 94 | 92 |
| Creep (%) | 0 | 0 | 5 | 22 | 54 |

TABLE 2

| Properties | Composite structure | | | | |
|---|---|---|---|---|---|
| | Film b/Resin combination | | | Film c/Resin combination | |
| | Film b/Resin A | Film b/Resin B | Film b/Resin C | Film c/Resin A | Film c/Resin B |
| Thickness (µm) | 40/25 | 40/25 | 40/25 | 40/25 | 40/25 |
| Modulus (MPa) | 950 | 944 | 1000 | 2930 | 2920 |
| εγ (%) | 2.1 | 2.1 | 2 | 1.9 | 2 |
| Cycle (%) | 92 | 93 | 92 | 90 | 90 |
| Creep (%) | 11 | 10 | 15 | 35 | 33 |

As shown in Table 2, in a case where the first layer 21 is Film b and the second layer 22 includes Resin A, B, or C in the first film 20, the first film 20 may satisfy the elastic modulus, yield strain, recovery rate, and viscoelastic strain described above with reference to embodiments of the invention. On the other hand, when the first layer 21 includes Film c and the second layer 22 includes Resin A, B, or C, in the first film 20 which is a comparative example, the elastic modulus of the first film 20 is too high so that the display panel 10 may not be folded or an excessive force may be used when the display panel 10 is folded.

The second adhesive layer 81 may be on the first film 20. The second adhesive layer 81 may be one of a pressure sensitive adhesive (“PSA”), an optical clear adhesive (“OCA”), and an optical clear resin (“OCR”). In an embodiment, for example, the second adhesive layer 81 may be a PSA.

The second film 30 may be on the second adhesive layer 81. The second film 30 is on the second adhesive layer 81, and may have a constant thickness. In an embodiment, the thickness of the second film 30 may be about 50 µm or less. Alternatively, the thickness of the second film 30 may be in a range of about 20 µm to about 50 µm, or in a range of about 10 µm to about 50 µm, and may be variously modified to be in another range, such as about 5 µm to about 50 µm. If the thickness of the second film 30 is less than about 20 µm, the display panel 10 may be damaged from an external impact because the thickness of the second film 30 is small. If the thickness of the second film 30 is greater than about 50 µm, the thickness of layers provided on the display panel 10 may increase, and thus the folding properties of the display device 1 may be deteriorated. Accordingly, in an embodiment, the thickness of the second film 30 is in the range of about 20 µm to about 50 µm, such that damage to the display panel 10 from an external impact may be effectively prevented or substantially minimized, and at the same time, the display device 1 may be easily folded.

In an embodiment, the second film 30 may include ultra-thin glass (“UTG”) or colorless polyimide (“CPI”).

A third film 40 may be on the second film 30. In an embodiment, the third film 40 may include an optical functional layer. The optical functional layer may reduce the reflectance of light (external light) incident from the outside toward the display device 1, and/or may improve the color purity of light emitted from the display device 1. In an embodiment, the optical functional layer may include a retarder and a polarizer. The retarder may be of a film type or a liquid crystal coating type, and may include a λ/2 retarder and/or a λ/4 retarder. The polarizer may also be of a film type or a liquid crystal coating type. The polarizer of the film type may include a stretch-type synthetic resin film, and the polarizer of the liquid crystal coating type may include liquid crystals arranged in a certain arrangement. The retarder and the polarizer may further include a protective film.

A third adhesive layer 84 may be between the second film 30 and the third film 40. In this case, because the third adhesive layer 84 is the same as or similar to the first adhesive layer 83 described above, any repetitive detailed description thereof will be omitted.

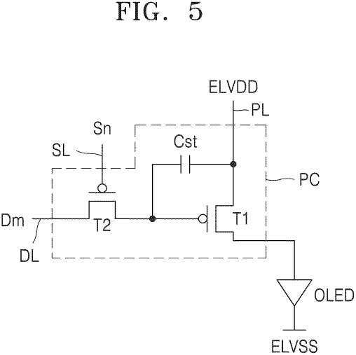

FIG. 4 is a plan view of the display panel 10 shown in FIG. 1.

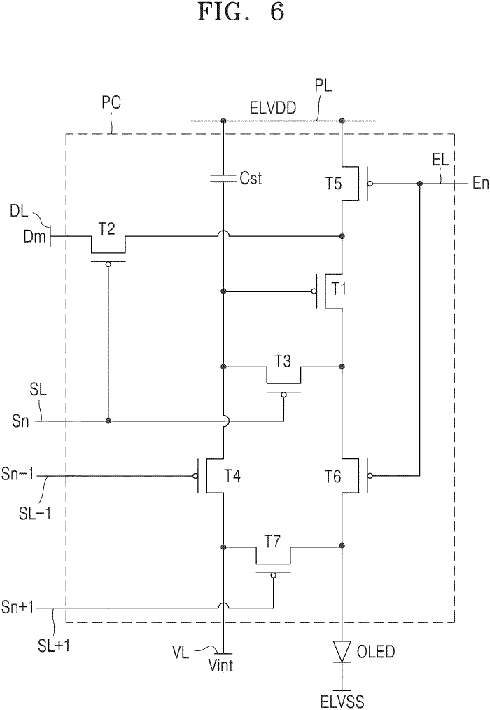

Referring to FIG. 4, in an embodiment, various components constituting the display panel 10 may be arranged or disposed on a substrate 100. The substrate 100 may include the display area DA and the peripheral area PA surrounding the display area DA. Pixels P may be arranged on the substrate 100 in the display area DA. Each of the pixels P may be implemented as including a display element such as an organic light-emitting diode OLED (see FIG. 5). Each pixel P may emit, for example, red, green, blue, or white light. The display area DA may be covered with a sealing member to be protected from external air or moisture.

for driving the pixels P may be electrically connected to outer circuits arranged in the peripheral area PA, respectively. A first scan driving circuit SDRV1, a second scan driving circuit SDRV2, a terminal portion PAD, a driving voltage supply line 11, and a common voltage supply line 13 may be arranged in the peripheral area PA.

The first scan driving circuit SDRV1 may apply a scan signal to each of the pixel circuits driving the pixels P through a scan line SL. The first scan driving circuit SDRV1 may apply an emission control signal to each pixel circuit through an emission control line EL. The second scan driving circuit SDRV2 may be located opposite to the first scan driving circuit SDRV1 with respect to the display area DA and may be parallel to the first scan driving circuit SDRV1. Some of the pixel circuits of the pixels P of the display area DA may be electrically connected to the first scan driving circuit SDRV1, and the rest may be electrically connected to the second scan driving circuit SDRV2.

The terminal portion PAD may be on one side of the substrate 100. The terminal portion PAD may be exposed without being covered by an insulating layer to be connected to a display circuit board 15. A display driver 17 may be arranged on the display circuit board 15.

The display driver 17 may generate a control signal transmitted to the first scan driving circuit SDRV1 and the second scan driving circuit SDRV2. The display driver 17 may generate a data signal, and the generated data signal may be transmitted to the pixel circuits of the pixels P through a fan-out wire FW and a data line DL connected to the fan-out wire FW.

The display driver 17 may supply a driving voltage ELVDD (see FIG. 5) to the driving voltage supply line 11 and may supply a common voltage ELVSS (see FIG. 5) to the common voltage supply line 13. The driving voltage ELVDD may be applied to the pixel circuits of the pixels P through a driving voltage line PL connected to the driving voltage supply line 11, and the common voltage ELVSS may be connected to the common voltage supply line 13 and applied to an opposite electrode of the display element.

The driving voltage supply line 11 may extend in an x direction from a lower side of the display area DA. The common voltage supply line 13 has a loop shape with one side open, and may partially surround the display area DA.

FIGS. 5 and 6 are equivalent circuit diagrams of a pixel circuit PC for driving a pixel according to an embodiment.

Referring to FIGS. 5 and 6, in an embodiment, a pixel circuit PC may be connected to the organic light-emitting diode OLED to realize light emission of a pixel. The pixel circuit PC includes a driving thin-film transistor T1, a switching thin-film transistor T2, and a storage capacitor Cst. The switching thin-film transistor T2 may be connected to the scan line SL and the data line DL, and may transmit a data signal Dm received through the data line DL to the driving thin-film transistor T1 in response to the scan signal Sn received through the scan line SL.

As shown in FIG. 5, the storage capacitor Cst may be connected to the switching thin-film transistor T2 and the driving voltage line PL, and may store a voltage corresponding to a difference between a voltage received from the switching thin-film transistor T2 and the driving voltage ELVDD supplied to the driving voltage line PL.

The driving thin-film transistor T1 may be connected to the driving voltage line PL and the storage capacitor Cst, and may control a driving current flowing from the driving voltage line PL to the organic light-emitting diode OLED in response to a voltage value stored in the storage capacitor Cst. The organic light-emitting diode OLED may emit light having certain luminance corresponding to the driving current.

Although FIG. 5 shows an embodiment where the pixel circuit PC includes two thin-film transistors and one storage capacitor, the disclosure is not limited thereto.

In an alternative embodiment, as shown in FIG. 6, the pixel circuit PC may include the driving thin-film transistor T1, the switching thin-film transistor T2, a compensation thin-film transistor T3, a first initialization thin-film transistor T4, an operation control thin-film transistor T5, an emission control thin-film transistor T6, and a second initialization thin-film transistor T7.

Although FIG. 6 shows an embodiment where signal lines SL, SL-1, SL+1, EL, and DL, an initialization voltage line VL, and the driving voltage line PL are provided for each pixel circuit PC, the disclosure is not limited thereto. In an alternative embodiment, at least one selected from the signal lines SL, SL-1, SL+1, EL, and DL, and the initialization voltage line VL may be shared by neighboring pixel circuits. The signal lines SL, SL-1, SL+1, EL, and DL comprise the scan line SL, previous scan line SL-1, the subsequent scan line SL+1, the emission control line EL and the data line DL.

A drain electrode of the driving thin-film transistor T1 may be electrically connected to the organic light-emitting diode OLED via the emission control thin-film transistor T6. The driving thin-film transistor T1 may receive the data signal Dm in response to a switching operation of the switching thin-film transistor T2 and supply a driving current to the organic light-emitting diode OLED.

A gate electrode of the switching thin-film transistor T2 may be connected to the scan line SL and a source electrode of the switching thin-film transistor T2 may be connected to the data line DL. A drain electrode of the switching thin-film transistor T2 may be connected to a source electrode of the driving thin-film transistor T1 and may further be connected to the driving voltage line PL via the operation control thin-film transistor T5.

The switching thin-film transistor T2 may be turned on in response to the scan signal Sn received through the scan line SL and may perform a switching operation for transmitting the data signal Dm transmitted to the data line DL to the source electrode of the driving thin-film transistor T1.

A gate electrode of the compensation thin-film transistor T3 may be connected to the scan line SL. A source electrode of the compensation thin-film transistor T3 may be connected to the drain electrode of the driving thin-film transistor T1 and may further be connected to a pixel electrode of the organic light-emitting diode OLED via the emission control thin-film transistor T6. A drain electrode of the compensation thin-film transistor T3 may be connected to any one electrode of the storage capacitor Cst, a source electrode of the first initialization thin-film transistor T4, and a gate electrode of the driving thin-film transistor T1. The compensation thin-film transistor T3 is turned on in response to the scan signal Sn received through the scan line SL to connect the gate electrode and the drain electrode of the driving thin-film transistor T1 to each other, thereby diode-connecting the driving thin-film transistor T1.

A gate electrode of the first initialization thin-film transistor T4 may be connected to the previous scan line SL-1. A drain electrode of the first initialization thin-film transistor T4 may be connected to the initialization voltage line VL. A source electrode of the first initialization thin-film transistor T4 may be connected together to the any one electrode of the storage capacitor Cst, the drain electrode of the compensation thin-film transistor T3, and the gate electrode of the driving thin-film transistor T1. The first initialization thin-film transistor T4 may be turned on in response to a previous scan signal Sn-1 received through the previous scan line SL-1 to transmit an initialization voltage Vint to the gate electrode of the driving thin-film transistor T1 to perform an initialization operation for initializing a voltage of the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 is connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the organic light-emitting diode OLED. The operation control thin-film transistor T5 and the emission control thin-film transistor T6 are simultaneously turned on in response to an emission control signal En received through the emission control line EL so that the driving voltage ELVDD is transmitted to the organic light-emitting diode OLED, and a driving current flows through the organic light-emitting diode OLED.

A gate electrode of the second initialization thin-film transistor T7 may be connected to the subsequent scan line SL+1. A source electrode of the second initialization thin-film transistor T7 may be connected to the pixel electrode of the organic light-emitting diode OLED. A drain electrode of the second initialization thin-film transistor T7 may be connected to the initialization voltage line VL. The second initialization thin-film transistor T7 may be turned on in response to a subsequent scan signal Sn+1 received through the subsequent scan line SL+1 to initialize the pixel electrode of the organic light-emitting diode OLED.

Although FIG. 6 shows an embodiment where the first initialization thin-film transistor T4 and the second initialization thin-film transistor T7 are connected to the previous scan line SL-1 and the subsequent scan line SL+1, respectively, the disclosure is not limited thereto. In an alternative embodiment, both the first initialization thin-film transistor T4 and the second initialization thin-film transistor T7 may be connected to the previous scan line SL-1 to be driven in response to the previous scan signal Sn-1.

The other electrode of the storage capacitor Cst may be connected to the driving voltage line PL. The any one electrode of the storage capacitor Cst may be connected together to the gate electrode of the driving thin-film transistor T1, the drain electrode of the compensation thin-film transistor T3, and the source electrode of the first initialization thin-film transistor T4.

An opposite electrode (e.g., cathode) of the organic light-emitting diode OLED may receive the common voltage ELVSS. The organic light-emitting diode OLED may receive a driving current from the driving thin-film transistor T1 to emit light.

The pixel circuit PC is not limited to the circuit design and the number of thin-film transistors and storage capacitors described with reference to FIGS. 5 and 6, and the circuit design of pixel circuits PC and the number of thin-film transistors and storage capacitors of pixel circuits PC may be variously modified.

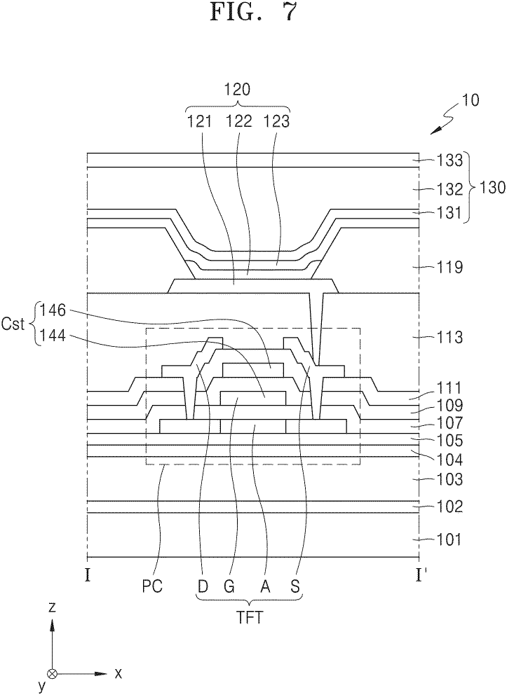

FIG. 7 is a cross-sectional view of a cross-section of the display device 1 (see FIGS. 1 to 3) according to an embodiment. In more detail, FIG. 7 is a cross-sectional view of the display panel 10 taken along line I-I' of FIG. 4.

Hereinafter, a stacked structure of the display panel 10 will be briefly described with reference to FIG. 7.

Referring to FIG. 7, the display panel 10 may include a first base layer 101, a first barrier layer 102, a second base layer 103, and a second barrier layer 104 sequentially stacked. The first base layer 101 and the second base layer 103 may be formed of a polymer resin having high heat resistance. In an embodiment, for example, the first base layer 101 and the second base layer 103 may include at least one selected from polyether sulfone, polyacrylate, polyether imide, polyethylene naphthalate, polyethylene terephthalate, polyphenylene sulfide, polyarylate, polyimide, polycarbonate, cellulose triacetate, cellulose acetate propionate, and polyarylene ether sulfone. In an embodiment, for example, the first base layer 101 and the second base layer 103 may include polyimide.

The first barrier layer 102 may be between the first base layer 101 and the second base layer 103. The first barrier layer 102 may be on the first base layer 101 to reduce or block penetration of foreign substances, moisture, or outside air from the bottom.

The second barrier layer 104 may be on the second base layer 103. The second barrier layer 104 may be on the second base layer 103 to reduce or block penetration of foreign substances, moisture, or outside air from the bottom.

The first barrier layer 102 and the second barrier layer 104 may include an inorganic insulating material such as silicon oxide (SiOx) silicon nitride (SiNx), silicon oxynitride (SiOₓN_{Y}), aluminum oxide (Al₂O₃), titanium oxide (TiO₂), tantalum oxide (Ta₂O₅), hafnium oxide (HfO₂), or zinc oxide (ZnOx). Here, ZnOx may be zinc oxide (ZnO) and/or zinc peroxide (ZnO₂). In an embodiment, the first barrier layer 102 and the second barrier layer 104 may include or be formed of a same material as each other. In an embodiment, for example, the first barrier layer 102 and the second barrier layer 104 may be formed of SiOx. In an embodiment, the first barrier layer 102 and the second barrier layer 104 may include or be formed of different materials from each other. In an alternative embodiment, the first barrier layer 102 and/or the second barrier layer 104 may be omitted.

A buffer layer 105 may be on the second barrier layer 104. The buffer layer 105 may be located on the first base layer 101 and the second base layer 103 to reduce or block penetration of foreign substances, moisture, or outside air from the bottom, and may provide a flat top surface.

The buffer layer 105 may include an inorganic insulating material such as SiOx, SiNₓ, SiOₓN_{Y}, Al₂O₃, TiO₂, Ta₂O₅, HfO₂, or ZnOₓ. Here, ZnOₓ may be ZnO and/or ZnO₂.

In an embodiment, the buffer layer 105 may include a first buffer layer and a second buffer layer. In an embodiment, the first buffer layer and the second buffer layer may include or be formed of a same material as each other. In an embodiment, the first buffer layer and the second buffer layer may include or be formed of different materials from each other.

A thin-film transistor TFT and the storage capacitor Cst of a pixel circuit PC may be arranged on the buffer layer 105. The thin-film transistor TFT may include a semiconductor layer A, a gate electrode G, a source electrode S, and a drain electrode D. The storage capacitor Cst may include a lower electrode 144 and an upper electrode 146. The thin-film transistor TFT in FIG. 7 may be for example the driving thin-film transistor T1 in FIG. 5. The organic light-emitting diode 120 in FIG. 7 may be for example the organic light-emitting diode OLED in FIG. 5.

In an embodiment, the semiconductor layer A is on the buffer layer 105 and may include polysilicon. In an embodiment, the semiconductor layer A may include amorphous silicon. In an embodiment, the semiconductor layer A may include an oxide of at least one selected from indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer A may include a channel area, and a source area and a drain area doped with impurities.

A first insulating layer 107 may be provided to cover the semiconductor layer A. The first insulating layer 107 may include an inorganic insulating material such as SiOx,

SiNₓ, SiOₓN_{Y}, Al₂O₃, TiO₂, Ta₂O₅, HfO₂, or ZnOₓ. Here, ZnOₓ may be ZnO and/or ZnO₂. The first insulating layer 107 may be a single layer or multiple layers including the above-described inorganic insulating material.

The gate electrode G may be arranged on the first insulating layer 107 to overlap the semiconductor layer A. The gate electrode G includes molybdenum (Mo), aluminum (Al), copper (Cu), or titanium (Ti) and may be formed as or defined by a single layer or multiple layers. In an embodiment, the gate electrode G may be a single layer of Mo.

A second insulating layer 109 may be provided to cover the gate electrode G. The second insulating layer 109 may include an inorganic insulating material such as SiOₓ, SiNₓ, SiOₓN_{Y}, Al₂O₃, TiO₂, Ta₂O₅, HfO₂, or ZnOₓ. Here, ZnOₓ may be ZnO and/or ZnO₂. The second insulating layer 109 may be a single layer or multiple layers including the above-described inorganic insulating material.

The upper electrode 146 of a storage capacitor Cst may be on the second insulating layer 109. The upper electrode 146 may overlap the gate electrode G arranged therebelow. The gate electrode G and the upper electrode 146 overlapping each other with the second insulating layer 109 therebetween may form the storage capacitor Cst. In an embodiment, the gate electrode G may be the lower electrode 144 of the storage capacitor Cst. In an embodiment, the lower electrode 144 of the storage capacitor Cst may be provided as a separate and independent component.

The upper electrode 146 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multiple layers of the above-described materials.

A third insulating layer 111 may be formed to cover the upper electrode 146. The third insulating layer 111 may include an inorganic insulating material such as SiOx, SiNx, SiOₓN_{Y}, Al₂O₃, TiO₂, Ta₂O₅, HfO₂, or ZnOₓ. Here, ZnOₓ may be ZnO and/or ZnO₂.The third insulating layer 111 may be a single layer or multiple layers including the above-described inorganic insulating material.

The source electrode S and the drain electrode D may be arranged on the third insulating layer 111. The source electrode S and the drain electrode D may include a conductive material including Mo, Al, Cu, Ti, or the like, and may be formed as or defined by a single layer or multiple layers including the above-described conductive materials. In an embodiment, the source electrode S and the drain electrode D may have a multilayer structure of Ti/Al/Ti.

A planarization layer 113 may be arranged to cover the source electrode S and the drain electrode D. The planarization layer 113 may have a flat top surface so that a pixel electrode 121 arranged thereon may be formed flat.

The planarization layer 113 may include an organic material or an inorganic material, and may have a single layer structure or a multilayer structure. The planarization layer 113 may include a general polymer such as benzocyclobutene (“BCB”), polyimide (“PI”), hexamethyldisiloxane (“HMDSO”), polymethylmethacrylate (“PMMA”), and polystyrene (“PS”), a polymer derivative including a phenolic group, an acrylic polymer, an imide polymer, an aryl ether polymer, an amide polymer, a fluorine-based polymer, a p-xylene-based polymer, a vinyl alcohol polymer, or a blend thereof. The planarization layer 113 may include an inorganic insulating material such as SiOx, SiNx, SiOₓN_{Y}, Al₂O₃, TiO₂, Ta₂O₅, HfO₂, or ZnOₓ. Here, ZnOₓ may be ZnO and/or ZnO₂. When the planarization layer 113 is formed, chemical mechanical polishing may be performed on the planarization layer 113 to provide a flat top surface.

A via hole exposing any one of the source electrode S and the drain electrode D of the thin-film transistor TFT may be defined through the planarization layer 113, and the pixel electrode 121 may be in contact with the source electrode S or the drain electrode D through the via hole to be electrically connected to the thin-film transistor TFT.

In an embodiment, the planarization layer 113 may include a first planarization layer and a second planarization layer. In an embodiment, the first planarization layer and the second planarization layer may include or be formed of a same material as each other. In an embodiment, the first planarization layer and the second planarization layer may include or be formed of different materials from each other. Because the planarization layer 113 is provided as the first planarization layer and the second planarization layer, the degree of integration of the display device may be improved.

The pixel electrode 121 may be arranged on the planarization layer 113. The pixel electrode 121 may include a conductive oxide such as indium tin oxide (ITO), indium zinc oxide (“IZO”), zinc oxide (ZnO), indium oxide (In₂O₃), indium gallium oxide (“IGO”), or aluminum zinc oxide (“AZO”). The pixel electrode 121 may include a reflective layer including Ag, Mg, Al, Pt, Pd, Au, Ni, Nd, Ir, Cr, or a compound thereof. In an embodiment, for example, the pixel electrode 121 may have a structure in which layers formed of ITO, IZO, ZnO, or In₂O₃ are arranged above and below the above-described reflective layer. In an embodiment, for example, the pixel electrode 121 may have a stacked structure of ITO/Ag/ITO.

A pixel-defining layer 119 may be on the planarization layer 113. The pixel-defining layer 119 is on the planarization layer 113 and may cover an edge of the pixel electrode 121. An opening exposing at least a portion of the pixel electrode 121 may be defined in the pixel-defining layer 119.

The pixel-defining layer 119 may prevent an arc or the like from occurring at the edge of the pixel electrode 121 by increasing a distance between the edge of the pixel electrode 121 and an opposite electrode 123 above the pixel electrode 121. The pixel-defining layer 119 may include an organic insulating material such as PI, polyamide, acrylic resin, BCB, HMDSO, and phenolic resin, and may be formed by spin coating.

Although not shown, a spacer for preventing damage to a mask may be further arranged on the pixel-defining layer 119. The spacer may be integrally formed with the pixel-defining layer 119 as a single unitary unit. In an embodiment, for example, the spacer and the pixel-defining layer 119 may be simultaneously formed in a same process using a half tone mask process.

An intermediate layer 122 may be arranged in an opening of the pixel-defining layer 119 to correspond to the pixel electrode 121. The intermediate layer 122 may include a light emitting layer. The light emitting layer may include a high molecular weight organic material or a low molecular weight organic material, and may emit red, green, blue, or white light.

In an embodiment, the intermediate layer 122 may further include an organic functional layer arranged above and/or below the light emitting layer. The organic functional layer may include a first functional layer and/or a second functional layer. In an alternative embodiment, the first functional layer and/or the second functional layer may be omitted.

The first functional layer may be below the light emitting layer. The first functional layer may be a single layer or multiple layers including or made of organic materials. The first functional layer may be a hole transport layer having a single layer structure. Alternatively, the first functional layer may include a hole injection layer and the hole transport layer.

The second functional layer may be on the light emitting layer. The second functional layer may be a single layer or multiple layers including or made of organic materials. The second functional layer may include an electron transport layer ETL and/or an electron injection layer EIL.

The opposite electrode 123 may be on the intermediate layer 122. The opposite electrode 123 may include a conductive material having a low work function. In an embodiment, for example, the opposite electrode 123 may include a (semi) transparent electrode including Ag, Mg, Al, Pt, Pd, Au, Ni, Nd, Ir, Cr, or an alloy thereof. Alternatively, the opposite electrode 123 may further include a layer such as ITO, IZO, ZnO, or In₂O₃ on the (semi) transparent layer including the above-mentioned material.

In an embodiment, layers from the pixel electrode 121 to the opposite electrode 123 may form an organic light-emitting diode 120.

A capping layer (not shown) including an organic material may be formed on the opposite electrode 123. The capping layer may be a layer provided to protect the opposite electrode 123 and increase light extraction efficiency. The capping layer may include an organic material having a higher refractive index than that of the opposite electrode 123.

A thin film encapsulation layer 130 may be arranged as a sealing member on the organic light-emitting diode 120 of the display device 1 (see FIGS. 1 to 3). In an embodiment, the organic light-emitting diode 120 may be sealed by the thin film encapsulation layer 130. The thin film encapsulation layer 130 may be arranged on the opposite electrode 123. The thin film encapsulation layer 130 may prevent or minimize external moisture or foreign substances from penetrating into the organic light-emitting diode 120.

The thin film encapsulation layer 130 may include at least one inorganic layer and at least one organic layer. In an embodiment, the thin film encapsulation layer 130 may include a first inorganic layer 131, an organic layer 132, and a second inorganic layer 133 sequentially stacked one on another. In an embodiment, the number of organic layers and the number and stacking order of inorganic layers may be changed or variously modified.

The first inorganic layer 131 and the second inorganic layer 133 may include one or more inorganic insulating materials such as SiOx, SiNₓ, SiOₓN_{Y}, Al₂O₃, TiO₂, Ta₂O₅, HfO₂, or ZnOx, and may be formed by chemical vapor deposition (CVD) or the like. In this case, ZnOx may be ZnO and/or ZnO₂. The organic layer 132 may include a polymer-based material, such as silicone resin, acrylic resin, epoxy resin, polyimide, polyethylene, or the like, for example.

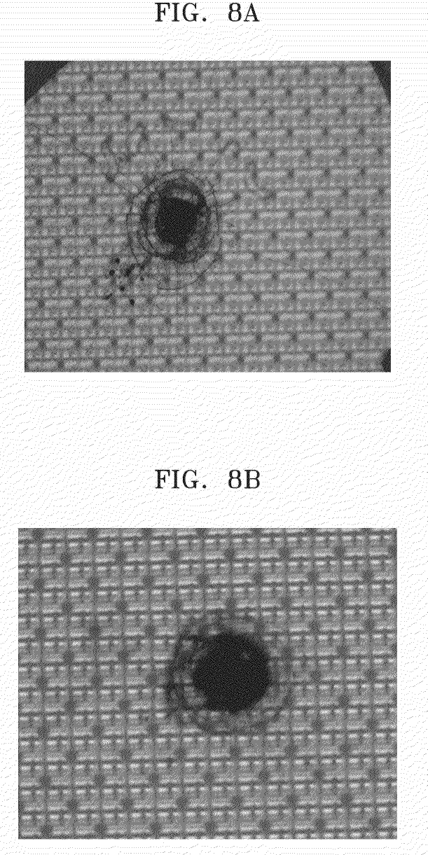

FIGS. 8A and 8B are plan views of experimental examples of a conventional display device and a display device according to an embodiment.

Referring to FIGS. 8A and 8B, various experimental methods may be used to confirm the impact resistance of the display device including the first film 20 as described above. In an embodiment, for example, to test the impact resistance of each film or display device, a pen having a diameter of about 0.3 centimeter (cm) is dropped from a certain height to check whether dark spots occur on the display panel or the second film 30 is damaged.

In the experimental examples, a thickness of a general first film used for an experimental example of a conventional display device (hereinafter, “comparative example”) and a thickness of the first film 20 used for an experimental example of a display device according to an embodiment (hereinafter, “experimental embodiment”) may be about 75 µm. In addition, the elastic modulus of the general first film used as the comparative example may be about 530 MPa, and the elastic modulus of the first film 20 used as the experimental example may be about 950 MPa.

As described above, a pen having a diameter of about 0.3 cm may be vertically dropped on a surface of the display device to test the impact resistance. In the case of the comparative example, when the pen is dropped from a height of about 8.3 cm, dark spots may occur on the display panel or the second film 30 may be damaged. On the other hand, in the case of the experimental embodiment, when the pen is dropped from a height of about 10.4 cm, dark spots may occur on the display panel or the second film 30 may be damaged.

In addition, when performing the above experiment, as shown in FIG. 8A, in the case of the comparative example, it can be confirmed that a crack propagates around a portion to which the pen has applied an impact. That is, when the pen falls on the display device and collides, the second film at a portion where the pen is in contact with the display device may be damaged, and cracks may occur in various directions around this portion of the second film.

However, in the case of the experimental embodiment or a display device according to embodiments, as shown in FIG. 8B, although a portion where the pen is in contact with the display device may be damaged, it can be seen that cracks may not propagate around this portion or the propagation of cracks may be reduced.

As described herein, embodiments of a display device according to the invention may prevent or minimize damage to a display panel from an external impact.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the attached claims.

What is claimed is:

1. A display device comprising:
a display panel in which a display element is disposed;
a first film on the display panel;
a second film on the first film; and
a first adhesive layer between the first film and the display panel,
wherein the first film comprises:
a first layer adjacent to the second film; and
a second layer between the first layer and the first adhesive layer, wherein an elastic modulus of the second layer is different from an elastic modulus of the first layer.

2. The display device of claim 1, wherein the elastic modulus of the first layer is greater than the elastic modulus of the second layer.

3. The display device of claim 1, wherein the elastic modulus of the first layer is in about 600 MPa or greater and about 1.5 GPa or less.

4. The display device of claim 1, wherein an elastic modulus of the first film is about 700 MPa or greater and about 1.2 GPa or less.

5. The display device of claim 1, wherein the elastic modulus of the second layer is about 5 MPa or greater and about 30 MPa or less.

6. The display device of claim 1, wherein the second layer includes an acryl-based and/or a silicone-based resin.

7. The display device of claim 1, further comprising:
a second adhesive layer between the first layer and the second film.

8. The display device of claim 1, further comprising:
a third film on the second film.

9. The display device of claim 8, further comprising:
a third adhesive layer between the third film and the second film.

10. The display device of claim 1, wherein a yield strain of the first film is about 2.9% or less.

11. A display device comprising:
a display panel;
a first film on the display panel;
a second film on the first film; and
a first adhesive layer between the first film and the display panel,
wherein the first film includes a first portion and a second portion having different elastic moduli from each other.

12. The display device of claim 11, wherein the elastic modulus of the first portion is greater than the elastic modulus of the second portion.

13. The display device of claim 11, wherein the elastic modulus of the first portion is about 600 MPa or greater and about 1.5 GPa or less.

14. The display device of claim 11, wherein the elastic modulus of the second portion is about 5 MPa or greater and about 30 MPa or less.

15. The display device of claim 11, wherein the second portion includes an acryl-based and/or a silicone-based resin.

16. The display device of claim 11, wherein an elastic modulus of the first film is about 700 MPa or greater and about 1.2 GPa or less.

17. The display device of claim 11, further comprising:
a second adhesive layer between the first film and the second film.

18. The display device of claim 11, further comprising:
a third film on the second film.

19. The display device of claim 18, further comprising:
a third adhesive layer between the third film and the second film.

20. The display device of claim 11, wherein a yield strain of the first film is about 2.9% or less.
